(19) United States
(12) Patent Application Publication
(10) Pub. No.: US 2026/0253649 A1
(43) Pub. Date: Aug. 27, 2026

(54) DETECTION METHOD AND SEMICONDUCTOR STORAGE DEVICE

(71) Applicant: Kioxia Corporation, Tokyo (JP)

(72) Inventors: Takayuki OKANO, Yokohama Kanagawa (JP); Hideki IGARASHI, Yokohama Kanagawa (JP)

(73) Assignee: Kioxia Corporation, Tokyo (JP)

(21) Appl. No.: 19/237,111

(22) Filed: Jun. 13, 2025

(30) Foreign Application Priority Data
Feb. 21, 2025 (JP) 2025-027219

(51) Int. Cl. G11C 16/34; G11C 16/28; G11C 29/02

(52) U.S. Cl. CPC G11C 16/3404; G11C 16/28; G11C 29/022

(57) ABSTRACT

A detection method according to the present embodiment includes acquiring the number of bits in which a threshold voltage of a word line in a first column range exceeds a first voltage range, and the number of bits in which a threshold voltage of the word line in a second column range exceeds the first voltage range. The present detection method includes detecting an anomaly in the word line based on a comparison between the number of bits exceeding the first voltage range in the first column range and the number of bits exceeding the first voltage range in the second column range.

### CROSS REFERENCE TO RELATED APPLICATIONS

This application is based upon and claims the benefit of priority from the prior Japanese Patent Application No. 2025-027219, filed on Feb. 21, 2025, the entire contents of which are incorporated herein by reference.

### FIELD

The embodiments of the present invention relate to detection method and a semiconductor storage device.

### BACKGROUND

It is a practice to mark a block that is not suitable for storing data as a bad block (defective block) in some cases. Typically, a timing of marking a bad block is when erasing/programming is executed and a status fails, or when ECC correction cannot be succeeded at the time of reading. However, in these methods, it may be difficult to predictively detect a defective cell.

### BRIEF DESCRIPTION OF THE DRAWINGS

FIG. 1 is a schematic block diagram illustrating a configuration of a semiconductor storage device according to a first embodiment;

FIG. 2 is a schematic circuit diagram illustrating a configuration of part of the semiconductor storage device according to the first embodiment;

FIG. 3 is a schematic block diagram illustrating a configuration of part of the semiconductor storage device according to the first embodiment;

FIG. 4 is a schematic circuit diagram illustrating a configuration of part of the semiconductor storage device according to the first embodiment;

FIG. 5 is a schematic perspective view illustrating a configuration of part of the semiconductor storage device according to the first embodiment;

FIG. 6 is a schematic enlarged view of a portion denoted by “A” in FIG. 5;

FIG. 7 is a diagram illustrating an example of a block configuration of the semiconductor storage device according to the first embodiment;

FIG. 8 is a graph illustrating an example of distribution of threshold voltages;

FIG. 9 is a diagram illustrating an example of an anomaly in the semiconductor storage device according to the first embodiment;

FIG. 10 is a diagram illustrating an example of an anomaly in the semiconductor storage device according to the first embodiment;

FIG. 11 is a diagram illustrating an example of a configuration of the semiconductor storage device according to the first embodiment;

FIG. 12 is a diagram illustrating an example of the configuration of the semiconductor storage device according to the first embodiment;

FIG. 13A is a diagram illustrating an example of predictive detection in the semiconductor storage device according to the first embodiment;

FIG. 13B is a diagram illustrating an example of predictive detection in the semiconductor storage device according to the first embodiment;

FIG. 13C is a diagram illustrating an example of predictive detection in the semiconductor storage device according to the first embodiment;

FIG. 14 is a diagram illustrating an example of predictive detection in the semiconductor storage device according to the first embodiment;

FIG. 15A is a diagram illustrating an example of predictive detection in the semiconductor storage device according to the first embodiment;

FIG. 15B is a diagram illustrating an example of predictive detection in the semiconductor storage device according to the first embodiment;

FIG. 16 is a diagram illustrating an example of an anomaly in the semiconductor storage device according to the first embodiment;

FIG. 17 is a schematic equivalent circuit diagram illustrating a configuration and an operation of the semiconductor storage device according to the first embodiment;

FIG. 18 is a flowchart illustrating an example of the operation of the semiconductor storage device according to the first embodiment;

FIG. 19 is a schematic equivalent circuit diagram illustrating the configuration and the operation of the semiconductor storage device according to the first embodiment;

FIG. 20 is a flowchart illustrating an example of the operation of the semiconductor storage device according to the first embodiment;

FIG. 21 is a schematic equivalent circuit diagram illustrating the configuration and the operation of the semiconductor storage device according to the first embodiment;

FIG. 22 is a flowchart illustrating an example of the operation of the semiconductor storage device according to the first embodiment;

FIG. 23 is a schematic equivalent circuit diagram illustrating the configuration and the operation of the semiconductor storage device according to the first embodiment;

FIG. 24 is a graph illustrating distribution of threshold voltages of the semiconductor storage device according to the first embodiment;

FIG. 25 is a flowchart illustrating an example of the operation of the semiconductor storage device according to the first embodiment; and

FIG. 26 is a schematic equivalent circuit diagram illustrating the configuration and the operation of the semiconductor storage device according to the first embodiment.

### DETAILED DESCRIPTION

Embodiments will now be explained with reference to the accompanying drawings. The present invention is not limited to the embodiments. It should be noted that the drawings are schematic or conceptual, and the relationship between the thickness and the width in each element and the ratio among the dimensions of elements do not necessarily match the actual ones. Even if two or more drawings show the same portion, the dimensions and the ratio of the portion may differ in each drawing. In the present specification and the drawings, elements identical to those described in the foregoing drawings are denoted by like reference characters and detailed explanations thereof are omitted as appropriate.

A detection method according to the present embodiment includes acquiring the number of bits in which a threshold voltage of a word line in a first column range exceeds a first voltage range, and the number of bits in which a threshold voltage of a word line in a second column range exceeds the first voltage range. The present detection method includes detecting an anomaly in the word line based on a comparison between the number of bits exceeding the first voltage range in the first column range and the number of bits exceeding the first voltage range in the second column range.

In the present specification, a predetermined direction parallel to a surface of a substrate is referred to as an X-direction, a direction that is parallel to the surface of the substrate and perpendicular to the X-direction is referred to as a Y-direction, and a direction perpendicular to the surface of the substrate is referred to as a Z-direction.

In the present specification, a direction along a predetermined surface may be referred to as a first direction, a direction intersecting with the first direction along the predetermined surface may be referred to as a second direction, and a direction intersecting with the predetermined surface may be referred to as a third direction. Each of these first direction, second direction, and third direction may correspond to any of the X-direction, the Y-direction, and the Z-direction, or does not necessarily correspond thereto.

In the present specification, representation such as “upper” or “lower” is based on the substrate. For example, a direction separated away from the substrate along the above-described first direction is referred to as “upper”, and a direction approaching the substrate along the first direction is referred to as “lower”. Regarding a certain configuration, a lower surface or a lower end means a surface or an end on the substrate side of this configuration, and an upper surface or an upper end means a surface or an end on the opposite side of the substrate of this configuration. A surface intersecting with the second direction or the third direction is referred to as a side surface and the like.

In the present specification, a “semiconductor storage device” may mean a memory die, or may mean a memory system including a control die such as a memory chip, a memory card, and an SSD. Furthermore, it may mean a configuration including a host computer such as a smartphone, a tablet terminal, and a personal computer.

In the present specification, in a case in which a first configuration is “electrically connected” to a second configuration, the first configuration may be directly connected to the second configuration, or the first configuration may be connected to the second configuration via wiring, a semiconductor member, a transistor, or the like. For example, in a case of three transistors connected in series, even if the second transistor is in an OFF state, the first transistor is “electrically connected” to the third transistor.

In the present specification, in a case in which the first configuration is “connected between” the second configuration and a third configuration, it may mean that the first configuration, the second configuration, and the third configuration are connected in series, and the first configuration is disposed on a current path of the second configuration and the third configuration.

In the present specification, in a case in which a circuit or the like brings two pieces of wiring and the like “into conduction”, for example, it may mean that this circuit or the like includes a transistor or the like, this transistor or the like is disposed on a current path between the two pieces of wiring, and this transistor or the like is caused to be in an ON state.

### First Embodiment

### [Configuration]

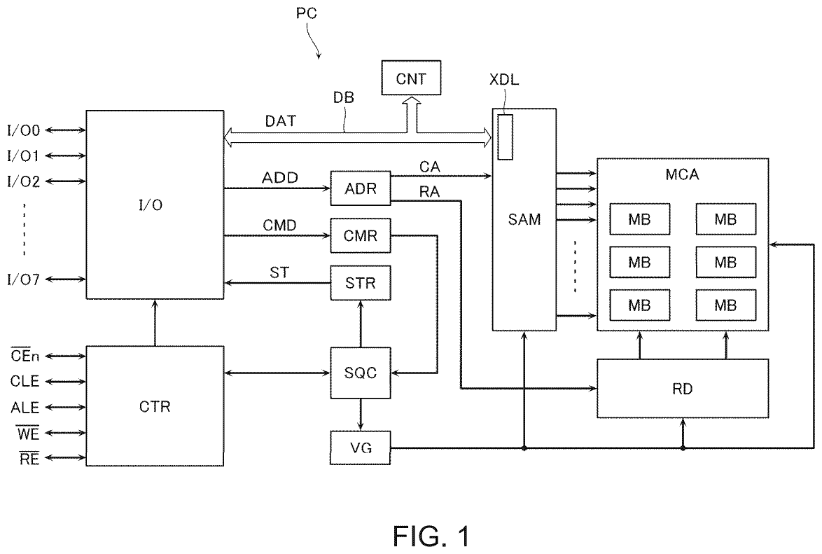

FIG. 1 is a schematic equivalent circuit diagram illustrating a configuration of a semiconductor storage device according to a first embodiment.

The semiconductor storage device according to the present embodiment includes a memory cell array MCA and a peripheral circuit PC configured to control the memory cell array MCA.

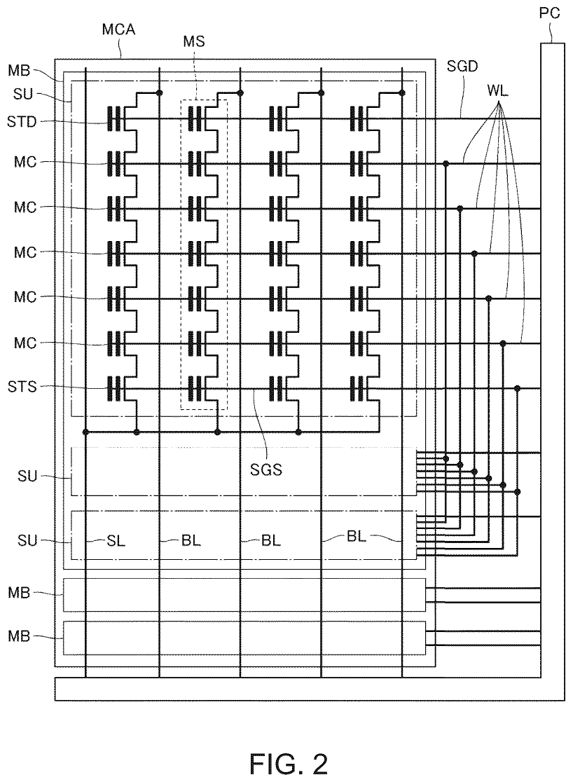

The memory cell array MCA includes a plurality of memory blocks MB. Each of the memory blocks MB includes a plurality of string units SU as illustrated in FIG. 2. Each of the string units SU includes a plurality of memory strings MS. One end of each of the memory strings MS is connected to the peripheral circuit PC via a bit line BL. The other end of each of the memory strings MS is connected to the peripheral circuit PC via a common source line SL.

The memory string MS includes a drain select transistor STD connected between the bit line BL and the source line SL in series, the plurality of memory cells MC, and a source select transistor STS. Hereinafter, the drain select transistor STD and the source select transistor STS may be simply referred to as selection transistors (STD, STS).

The memory cell MC is a field-effect transistor including a semiconductor layer that functions as a channel region, a gate insulation film including a charge trap film, and a gate electrode. A threshold voltage of the memory cell MC varies in accordance with a charge amount in the charge trap film. Word lines WL are respectively connected to gate electrodes of the plurality of memory cells MC corresponding to one of the memory strings MS. These word lines WL are respectively connected to all of the memory strings MS in one of the memory blocks MB in common.

The selection transistors (STD, STS) are field-effect transistors each including a semiconductor layer that functions as a channel region, a gate insulation film, and a gate electrode. Select gate lines (SGD, SGS) are respectively connected to gate electrodes of the selection transistors (STD, STS). A drain select line SGD is disposed corresponding to the string unit SU, and connected to all of the memory strings MS in one of the string units SU in common. A source select line SGS is connected to all of the memory strings MS in one of the memory blocks MB in common.

As illustrated in FIG. 1, the peripheral circuit PC includes a row decoder RD, a sense amplifier module SAM, a voltage generation circuit VG, a count circuit CNT, and a sequencer SQC. The peripheral circuit PC also includes an address register ADR, a command register CMR, and a status register STR. The peripheral circuit PC further includes an input/output control circuit I/O and a logic circuit CTR.

The row decoder RD includes, for example, a decode circuit and a switch circuit. The decode circuit decodes a row address RA held by the address register ADR. The switch circuit brings the select gate lines (SGD, SGS) and the word line WL corresponding to the row address RA into conduction with a corresponding voltage supply line in accordance with an output signal of the decode circuit.

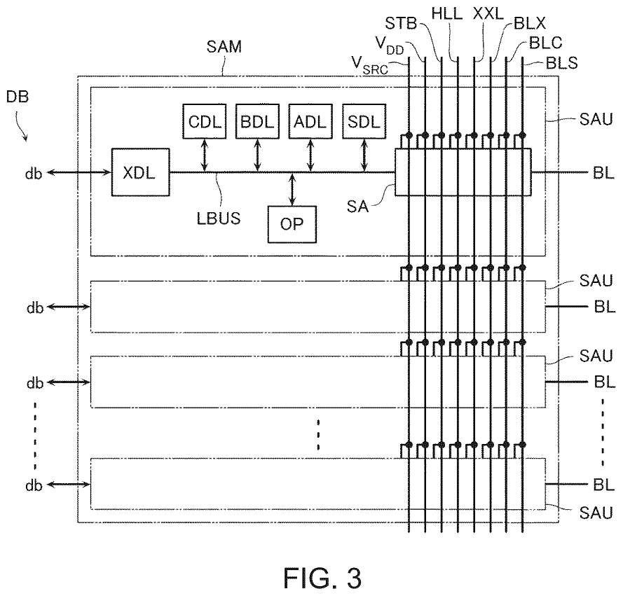

As illustrated in FIG. 3, the sense amplifier module SAM includes a plurality of sense amplifier units SAU corresponding to a plurality of the bit lines BL. The sense amplifier unit SAU includes a sense amplifier SA connected to the bit line BL, data latches SDL, ADL, BDL, CDL, and XDL, a logic circuit OP, and wiring LBUS connected to these configurations.

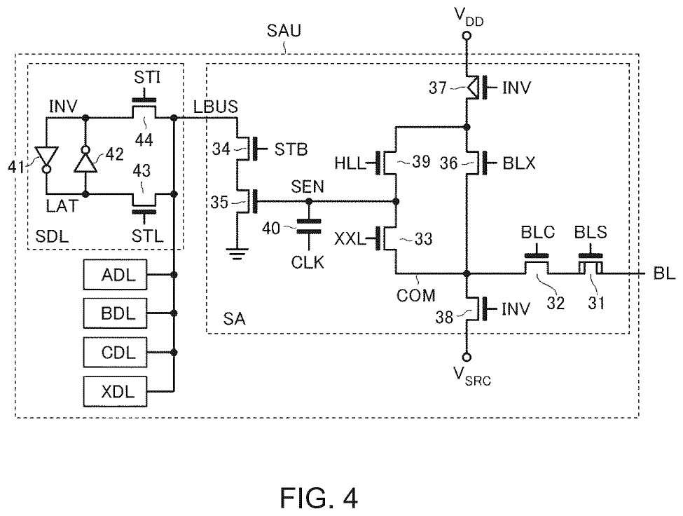

As illustrated in FIG. 4, the sense amplifier SA includes a high-voltage transistor 31 connected between the bit line BL and a sense node SEN in series, a clamp transistor 32, a node COM, and a discharge transistor 33. The sense amplifier SA also includes a switch transistor 34 and a sense transistor 35 connected in series between the wiring LBUS and a ground voltage supply line. The ground voltage supply line is connected to a pad electrode for supplying a ground voltage VSS.

The high-voltage transistor 31 is an NMOS-type high-voltage transistor. The high-voltage transistor 31 protects the sense amplifier SA when a relatively large voltage is supplied to the source line SL (FIG. 2), for example. A control signal from the sequencer SQC is supplied to a gate electrode of the high-voltage transistor 31 via a signal line BLS.

The clamp transistor 32 is an NMOS-type transistor. The clamp transistor 32 controls a voltage of the bit line BL. A control signal from the sequencer SQC is supplied to a gate electrode of the clamp transistor 32 via a signal line BLC.

The node COM is connected to a charge transistor 36, a charge transistor 37, and a power supply voltage supply line VDD. The power supply voltage supply line VDD is connected to a pad electrode for supplying a power supply voltage. The node COM is also connected to a voltage supply line VSRC via a discharge transistor 38. The charge transistor 36 and the discharge transistor 38 are NMOS-type transistors. The charge transistor 37 is a PMOS-type transistor. A control signal from the sequencer SQC is supplied to a gate electrode of the charge transistor 36 via a signal line BLX. Each of gate electrodes of the charge transistor 37 and the discharge transistor 38 is connected to a node INV of the data latch SDL.

The discharge transistor 33 is an NMOS-type transistor. The discharge transistor 33 discharges a charge of the sense node SEN. A control signal from the sequencer SQC is supplied to a gate electrode of the discharge transistor 33 via a signal line XXL.

The sense node SEN is connected to the power supply voltage supply line VDD via a charge transistor 39 and the charge transistor 37. The sense node SEN is also connected to a signal line CLK via a capacitor 40. A control signal from the sequencer SQC is supplied to the signal line CLK. The charge transistor 39 is an NMOS-type transistor. A control signal from the sequencer SQC is supplied to a gate electrode of the charge transistor 39 via a signal line HLL.

The switch transistor 34 is an NMOS-type transistor. The switch transistor 34 brings the wiring LBUS and the sense transistor 35 into conduction. A control signal from the sequencer SQC is supplied to a gate electrode of the switch transistor 34 via a signal line STB.

The sense transistor 35 is an NMOS-type transistor. The sense transistor 35 discharges or keeps charges in the wiring LBUS in accordance with a voltage of the sense node SEN. A gate electrode of the sense transistor 35 is connected to the sense node SEN.

As exemplified in FIG. 3, in the present embodiment, the signal lines BLS, BLC, BLX, XXL, HLL, and STB described above are connected in common among all of the sense amplifier units SAU included in the sense amplifier module SAM. In the present embodiment, the power supply voltage supply line VDD and the voltage supply line VSRC described above are connected in common among all of the sense amplifier units SAU included in the sense amplifier module SAM.

As illustrated in FIG. 4, the data latch SDL includes a node LAT, a node INV, inverters 41 and 42 connected between the node LAT and the node INV in parallel, a switch transistor 43 connected between the node LAT and the wiring LBUS, and a switch transistor 44 connected between the node INV and the wiring LBUS. An output terminal of the inverter 41 and an input terminal of the inverter 42 are connected to the node LAT. An input terminal of the inverter 41 and an output terminal of the inverter 42 are connected to the node INV. Although not illustrated in the drawings, each of the data latches ADL, BDL, CDL, and XDL has the same configuration as that of the data latch SDL.

For example, data included in the data latch SDL is appropriately transferred to the data latches ADL, BDL, and CDL. The logic circuit OP (FIG. 3) performs, for example, a logical operation such as AND, OR, or XOR on data in the data latches ADL, BDL, and CDL, and calculates user data assigned to the memory cell MC.

The data latch XDL is connected to the wiring LBUS and wiring db configuring a bus DB (FIG. 3). In the data latch XDL, for example, user data to be written into the memory cell MC or user data read out from the memory cell MC are stored.

The sense amplifier module SAM includes a decode circuit and a switch circuit (not illustrated). The decode circuit decodes a column address CA held by the address register ADR (FIG. 1). The switch circuit brings the data latch XDL corresponding to the column address CA into conduction with the bus DB in accordance with an output signal of the decode circuit.

The voltage generation circuit VG (FIG. 1) includes, for example, a boost circuit such as a charge pump circuit connected to the power supply voltage supply line VDD and the ground voltage supply line, a step-down circuit such as a regulator, and a plurality of voltage supply lines (not illustrated). In accordance with an internal control signal from the sequencer SQC, the voltage generation circuit VG generates a plurality of kinds of operation voltages supplied to the bit line BL, the source line SL, the word line WL, and the select gate lines (SGD, SGS) in a read operation, a write operation, and an erase operation for the memory cell array MCA, and outputs the operation voltages from the plurality of voltage supply lines at the same time.

The count circuit CNT is connected to the bus DB, and counts the number of pieces of data indicating “1” and the number of pieces of data indicating “0” among pieces of data included in the data latch XDL. The count circuit CNT can also count the number of pieces of data indicating “1” or “0” while performing thinning. That is, the number of the memory cells MC can be counted based on only some pieces of data held by the data latch XDL instead of counting the number of all pieces of data held by the data latch XDL.

The sequencer SQC successively decodes command data CMD held by the command register CMR, outputs it from a plurality of signal lines, and outputs an internal control signal to the row decoder RD, the sense amplifier module SAM, the voltage generation circuit VG, and the count circuit CNT. The sequencer SQC appropriately outputs status data indicating a state of itself to the status register STR. For example, in performing the write operation or the erase operation, the sequencer SQC outputs, as status data, information indicating whether the write operation or the erase operation has been normally ended.

The input/output control circuit I/O includes data input/output terminals I/O0 to I/O7, a shift register connected to these data input/output terminals I/O0 to I/O7, and a FIFO buffer connected to this shift register. The input/output control circuit I/O is eight pad electrodes, and outputs data input from the data input/output terminals I/O0 to I/O7 to the data latch XDL in the sense amplifier module SAM, the address register ADR, or the command register CMR in accordance with an internal control signal from the logic circuit CTR. The input/output control circuit I/O also outputs data input from the data latch XDL or the status register STR to the data input/output terminals I/O0 to I/O7.

The logic circuit CTR receives an external control signal from a control die CD via external control terminals /CEn, CLE, ALE, /WE, and /RE, and outputs an internal control signal to the input/output control circuit I/O in accordance with the external control signal.

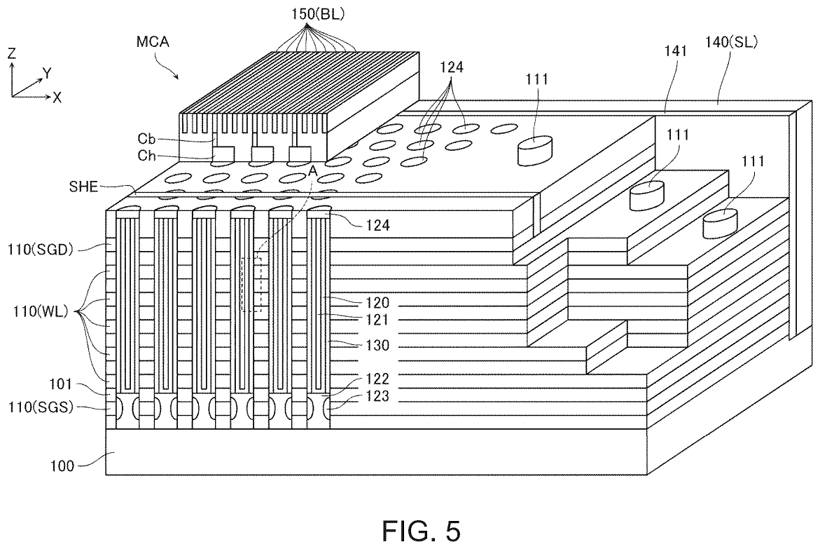

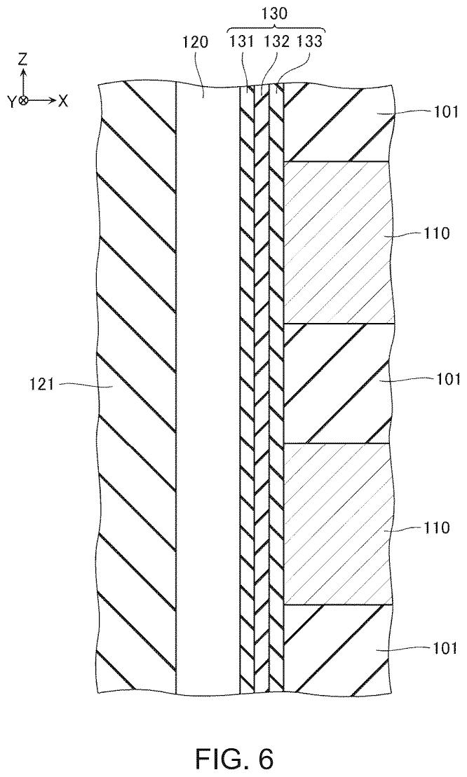

Next, the following describes a configuration example of the semiconductor storage device according to the present embodiment with reference to FIG. 5 and FIG. 6. FIG. 5 is a schematic perspective view illustrating a configuration of part of the semiconductor storage device according to the present embodiment. FIG. 6 is a schematic enlarged view of a portion denoted by “A” in FIG. 5.

As illustrated in FIG. 5, the semiconductor storage device according to the present embodiment includes a semiconductor substrate 100, a plurality of conductive layers 110 disposed on an upper side of the semiconductor substrate 100, a plurality of semiconductor layers 120, a plurality of gate insulation films 130 respectively disposed between the plurality of conductive layers 110 and the plurality of semiconductor layers 120, a conductive layer 140 connected to a surface of the semiconductor substrate 100, and conductive layers 150 connected to upper ends of the semiconductor layers 120.

The semiconductor substrate 100 is, for example, a semiconductor substrate such as single crystal silicon (Si) containing P-type impurities such as boron (B). An N-type well containing N-type impurities such as phosphorus (P) is disposed on part of the surface of the semiconductor substrate 100. A P-type well containing P-type impurities such as boron (B) is disposed on part of the surface of the N-type well.

The conductive layer 110 is a substantially plate-shaped conductive layer extending in the X-direction, and a plurality of the conductive layers 110 are arranged in the Z-direction. The conductive layer 110 may include, for example, a laminated film of titanium nitride (TiN) and tungsten (W) or the like, or may include polycrystalline silicon and the like containing impurities such as phosphorus or boron. An insulation layer 101 such as silicon oxide (SiO2) is disposed between the conductive layers 110.

Among the plurality of conductive layers 110, one or more of the conductive layers 110 positioned at the lowest level function as the source select line SGS (FIG. 2) and gate electrodes of a plurality of the source select transistors STS connected thereto. The plurality of conductive layers 110 positioned on an upper side thereof function as the word line WL (FIG. 2) and gate electrodes of the plurality of memory cells MC (FIG. 2) connected thereto. One or more of the conductive layers 110 positioned on an upper side thereof function as the drain select line SGD and gate electrodes of a plurality of the drain select transistors STD (FIG. 2) connected thereto. The conductive layer 110 that functions as the drain select transistor STD is divided in the Y-direction via an insulation layer SHE extending in the X-direction.

The plurality of semiconductor layers 120 are arranged in the X-direction and the Y-direction. The semiconductor layer 120 is, for example, a semiconductor film such as non-doped polycrystalline silicon (Si). The semiconductor layer 120 has a substantially cylindrical shape, and an insulation film 121 such as silicon oxide is disposed at a center thereof. Each outer peripheral surface of the semiconductor layer 120 is surrounded by the conductive layer 110. A lower end of the semiconductor layer 120 is connected to the P-type well of the semiconductor substrate 100 via a semiconductor layer 122 such as a non-doped single crystal silicon. The semiconductor layer 122 is opposed to the conductive layer 110 via an insulation layer 123 such as silicon oxide. An upper end of the semiconductor layer 120 is connected to the bit line BL via a semiconductor layer 124 containing N-type impurities such as phosphorus (P), and contacts Ch and Cb. The semiconductor layers 120 respectively functions as channel regions of the plurality of memory cells MC and the drain select transistor STD included in one of the memory strings MS (FIG. 2). The semiconductor layer 122 functions as a channel region of part of the source select transistor STS.

For example, as illustrated in FIG. 6, the gate insulation film 130 includes a tunnel insulation film 131, a charge trap film 132, and a block insulation film 133 laminated between the semiconductor layer 120 and the conductive layer 110. The tunnel insulation film 131 and the block insulation film 133 are, for example, insulation films such as silicon oxide. The charge trap film 132 is, for example, a film that can store electric charges, such as silicon nitride (SiN). The tunnel insulation film 131, the charge trap film 132, and the block insulation film 133 each have a substantially cylindrical shape, and extends in the Z-direction along an outer peripheral surface of the semiconductor layer 120.

Although FIG. 6 illustrates an example in which the gate insulation film 130 includes the charge trap film 132 such as silicon nitride, the gate insulation film 130 may include a floating gate such as polycrystalline silicon containing N-type or P-type impurities, for example.

The conductive layer 140 is, for example, as illustrated in FIG. 5, a substantially plate-shaped conductive layer extending in the X-direction and the Z-direction. The conductive layer 140 may include, for example, a laminated film of titanium nitride (TiN) and tungsten (W) or the like, or may include polycrystalline silicon and the like containing impurities such as phosphorus. An insulation layer 141 is disposed between the conductive layer 140 and the conductive layer 110. The conductive layer 140 functions as the source line SL.

The plurality of conductive layers 150 extend in the Y-direction and are arranged in the X-direction. The conductive layer 150 may include a laminated film of titanium nitride (TiN) and copper (Cu) or the like, or may include polycrystalline silicon and the like containing impurities such as phosphorus. The conductive layer 150 functions as the bit line BL.

### [Predictive Detection Method for Anomaly]

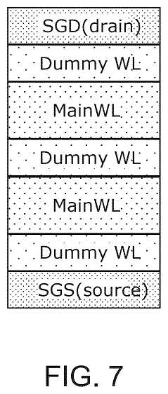

FIG. 7 is a diagram illustrating an example of a block configuration of the semiconductor storage device according to the first embodiment.

As described above with reference to FIG. 2, the drain select line SGD and the source select line SGS are disposed in the memory block MB. A dummy word line WL and a main word line WL are arranged between the drain select line SGD and the source select line SGS.

Erasing and writing are not performed on the drain select line SGD. The drain select line SGD is used for ON/OFF control of a cell.

The dummy word line WL does not have a memory function, and erasing and writing are not performed thereon.

The main word line WL is used for writing performed by a user.

Erasing and writing are not performed on the source select line SGS. The source select line SGS is used for ON/OFF control of a cell.

Herein, in the first embodiment, as described later, not only the main word line WL but also the select gate lines (SGD, SGS) and the dummy word line WL are targets of predictive detection. The main word line WL is a region in which a user of the semiconductor storage device performs erasing and writing, and a bit error that is caused when written data is read is corrected by control by the controller. In a case in which bit errors exceed correction limit, a block is marked as a bad block. In the first embodiment, an anomaly is detected before the bit errors cannot be corrected.

Next, the following describes the bit error.

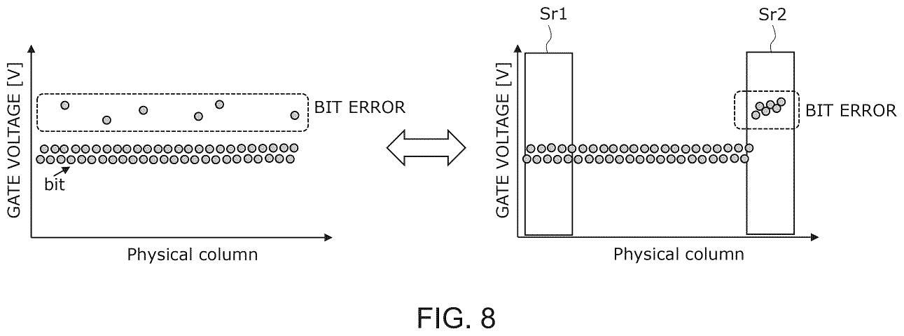

FIG. 8 is a graph illustrating an example of distribution of threshold voltages. A vertical axis in the graph indicates a gate voltage. A horizontal axis in the graph indicates a physical column (column).

A left side of FIG. 8 indicates distribution of threshold voltages in a case in which anomalies of bit errors are caused in a distributed manner across columns. A right side of FIG. 8 indicates distribution of threshold voltages in a case in which anomalies of bit errors are caused in a concentrated manner in close columns.

In the two graphs illustrated in FIG. 8, the numbers of bit errors are the same. In a case of acquiring levels of all bits and determining presence/absence of an anomaly based on a total number of fail bits, there is a concern that anomalies cannot be detected when the anomalies occur locally.

In the first embodiment, for example, a distribution anomaly is detected by comparing the numbers of bit errors between a plurality of search ranges Sr1 and Sr2. Due to this, a distribution anomaly of threshold voltages can be detected more easily.

Next, the following describes checking the distribution in a plurality of search ranges, for example, the two search ranges Sr1 and Sr2.

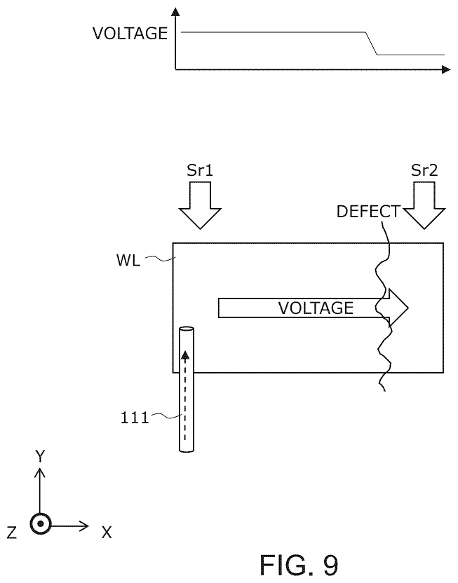

FIG. 9 is a diagram illustrating an example of an anomaly in the semiconductor storage device according to the first embodiment. An upper diagram in FIG. 9 is a graph indicating a relation between the threshold voltage and the physical column. A lower diagram in FIG. 9 is a diagram illustrating a positional relation between the one word line WL and a contact 111.

The contact 111 illustrated in FIG. 9 is connected to a left side end of the word line WL. An application direction of a voltage is a direction from the left to the right on a sheet surface of FIG. 9. The voltage can be applied to the word line WL via the contact 111. For example, when the word line WL has a defect, the voltage varies across the defect. That is, the voltage applied to the column before the defect is different from the voltage applied to the column after the defect.

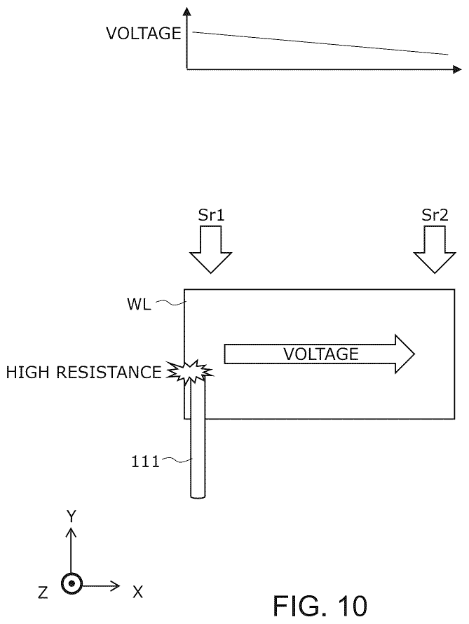

FIG. 10 is a diagram illustrating an example of an anomaly in the semiconductor storage device according to the first embodiment. An upper diagram in FIG. 10 is a graph indicating a relation between the threshold voltage and the physical column. A lower diagram in FIG. 10 is a diagram illustrating a positional relation between the one word line WL and the contact 111.

The contact 111 illustrated in FIG. 10 is connected to a left side end of the word line WL. The application direction of the voltage is a direction from the left to the right on a sheet surface of FIG. 10. The voltage can be applied to the word line WL via the contact 111. For example, in a case in which a connector between the word line WL and the contact 111 has high resistance, the voltage from the contact 111 is not normally applied to the word line WL. In a case in which the connector between the word line WL and the contact 111 is completely opened, it is detected as an anomaly earlier than predictive detection.

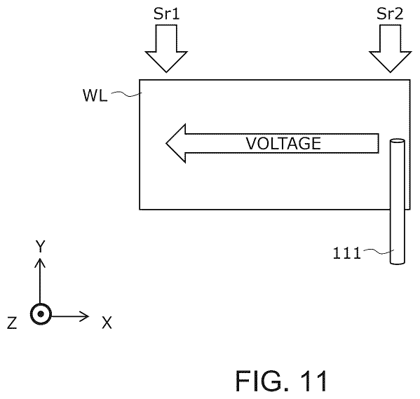

FIG. 11 is a diagram illustrating an example of a configuration of the semiconductor storage device according to the first embodiment.

The contact 111 illustrated in FIG. 11 is connected to a right side end of the word line WL. The application direction of the voltage is a direction from the right to the left on a sheet surface of FIG. 11. That is, the contact 111 may be connected to any of the left and right sides.

As illustrated in FIG. 9 and FIG. 10, a uniform voltage is not applied to the word line WL in some cases due to a defect in the word line WL or a defect in the connector between the word line WL and the contact 111 in some cases. It can be considered that a voltage difference becomes the largest between the connector between the word line WL and the contact 111 and an end on the opposite side of the contact 111, so that two points including a point close to the contact 111 and the end of the word line WL on the opposite side of the contact 111 are used as measurement areas (search ranges Sr1 and Sr2).

Next, the following explains that the select gate lines (SGD, SGS) and the dummy word line WL are targets of predictive detection.

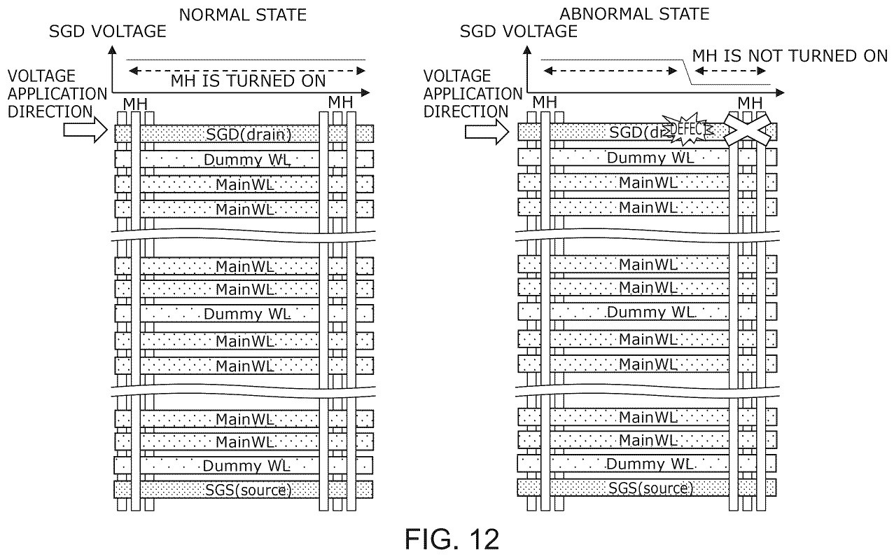

FIG. 12 is a diagram illustrating an example of a configuration of the semiconductor storage device according to the first embodiment. A left side of FIG. 12 illustrates an operation in a normal state. A right side of FIG. 12 illustrates an operation in an abnormal state due to a defect in the drain select line SGD.

FIG. 12 illustrates a memory hole MH in which the semiconductor layer 120, the tunnel insulation film 131, the charge trap film 132, and the block insulation film 133 are embedded.

The memory hole MH is not turned ON due to a defect in the drain select line SGD. In this case, a cell current does not flow, so that a bit error may be caused in all of the word lines WL.

Block configurations of a NAND cell are stacked in layers, so that influence of the one word line WL may extend to the other word line WL. Influence of the select gate lines (SGD, SGS) is large. That is, an anomaly in the select gate lines (SGD, SGS) and the dummy word line WL may influence the main word line WL. Thus, in the first embodiment, all layers are targets of previous preventive detection.

Next, the following describes details about predictive detection for the main word line WL.

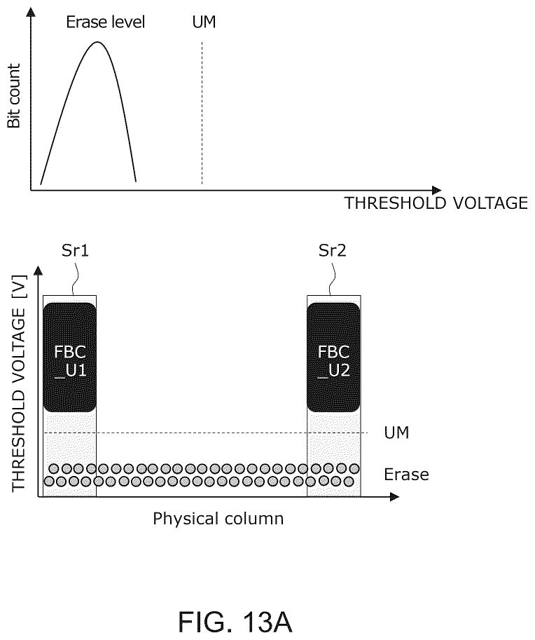

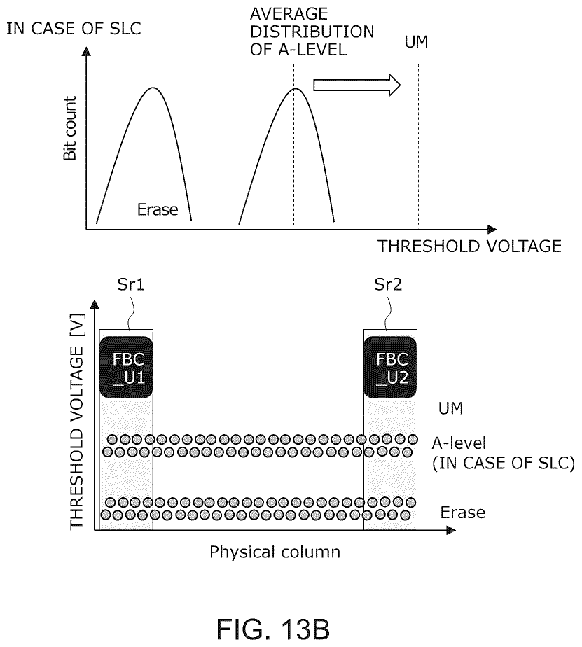

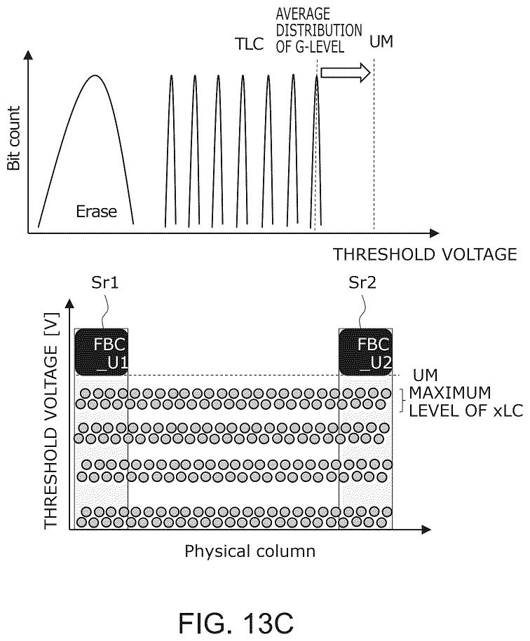

FIG. 13A to FIG. 13C are diagrams illustrating an example of predictive detection in the semiconductor storage device according to the first embodiment.

FIG. 13A to FIG. 13C illustrate predictive detection immediately after erasing, immediately after reading/programming, and at an optional timing. Upper diagrams in FIG. 13A to FIG. 13C are graphs indicating threshold voltage distribution. A vertical axis of the graph indicates a bit count. A horizontal axis of the graph indicates the threshold voltage. Lower diagrams in FIG. 13A to FIG. 13C are graphs indicating a relation between the threshold voltage and the physical column.

In FIG. 13A, a target is the main word line WL immediately after erasing, so that an expected value of the threshold voltage of the word line WL is at an erase level. An operation illustrated in FIG. 13A is performed by recognizing an erase operation by a command. The expected value at the time of erasing is clear, so that an upper-tail monitor UM (high voltage threshold) is set at a voltage higher than the erase level.

As a method of checking uniformity of threshold voltage distribution, one threshold (the upper-tail monitor UM) and two search ranges (the search range Sr1, the search range Sr2) are provided. Additionally, a total number of bits having a gate voltage higher than the upper-tail monitor UM in the search range Sr1 is defined as FailBitCount (hereinafter, referred to as FBC)_U1, and a total number of bits having a gate voltage higher than the upper-tail monitor UM in the search range Sr2 is defined as FBC_U2.

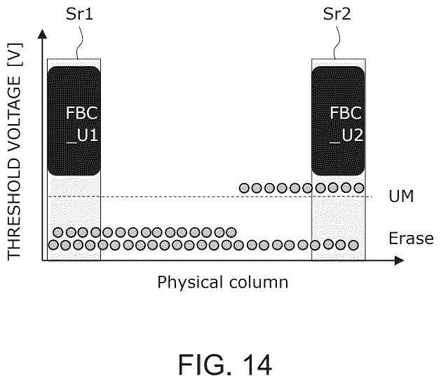

FIG. 14 is a diagram illustrating an example of predictive detection in the semiconductor storage device according to the first embodiment. FIG. 14 is a graph indicating a relation between the threshold voltage and the physical column.

The uniformity of the threshold voltage is determined by acquiring a difference between FBC_U1 and FBC_U2. In a case in which this difference exceeds a certain value, it is determined that there is an anomaly in threshold voltage distribution, and status fail determination is returned. With this method, the threshold voltage exhibiting column dependence can be determined to be an anomaly.

It is assumed that the search ranges Sr1 and Sr2 can be set for an optional column.

In FIG. 13B, the main word line WL immediately after reading/programming is the target, so that the threshold voltage of the word line WL is clear. An operation illustrated in FIG. 13B is performed by recognizing a read/program operation by a command. Based on a prefix command, xLC (a distribution pattern of threshold voltages) is determined. The upper-tail monitor UM (high voltage threshold) is set at a voltage higher than a maximum level of xLC. The upper-tail monitor UM is set at a voltage higher than the maximum level of xLC with a margin. FIG. 13B illustrates an example of a case of SLC.

In FIG. 13C, the main word line WL at an optional timing is the target, so that the threshold voltage of the word line WL is not clear in some cases. In a case in which the threshold voltage written in the main word line WL is unknown, the upper-tail monitor UM is set at a voltage higher than the maximum level that may be taken by a chip. The upper-tail monitor UM is set at a voltage higher than the maximum level of xLC with a margin. In a case in which the controller can discriminate a level written in a target block, the upper-tail monitor UM may be set by using the method in FIG. 13B. FIG. 13C illustrates an example of a case of TLC.

As a method of checking uniformity of threshold voltage distribution, one threshold (the upper-tail monitor UM) and two search ranges (the search range Sr1, the search range Sr2) are provided. Additionally, a total number of bits having a gate voltage higher than the upper-tail monitor UM in the search range Sr1 is defined as FBC_U1, and a total number of bits having a gate voltage higher than the upper-tail monitor UM in the search range Sr2 is defined as FBC_U2. As a change from FIG. 13A, in a case in which an expected value of the threshold voltage of the main word line WL not in an erase state is unknown, the upper-tail monitor UM is set to be a value exceeding the maximum level.

The uniformity of the threshold voltage is determined by acquiring a difference between FBC_U1 and FBC_U2. In a case in which this difference exceeds a certain value, it is determined that there is an anomaly in threshold voltage distribution, and status fail determination is returned. With this method, the threshold voltage exhibiting column dependence can be determined to be an anomaly.

It is assumed that the search ranges Sr1 and Sr2 can be set for an optional column.

Next, the following describes details of predictive detection for the select gate lines (SGD, SGS) and the dummy word line WL.

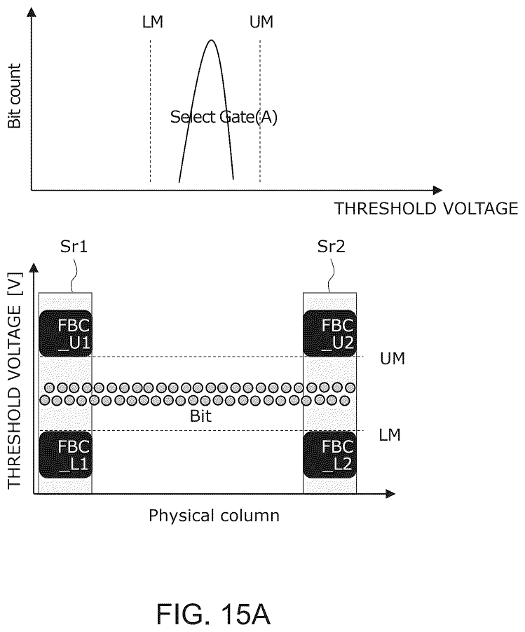

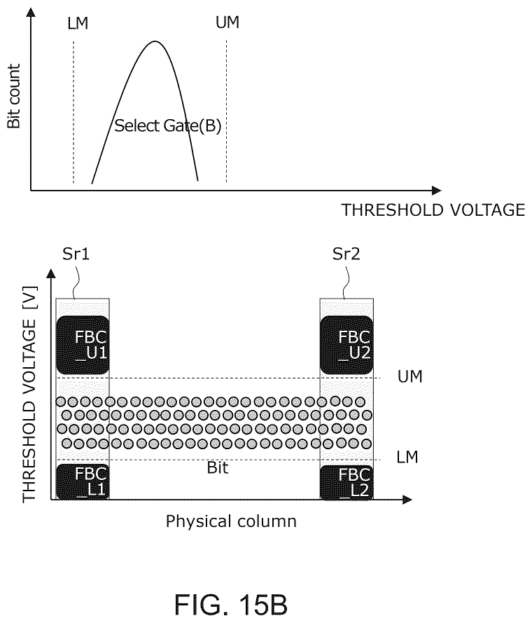

FIG. 15A and FIG. 15B are diagrams illustrating an example of predictive detection in the semiconductor storage device according to the first embodiment.

FIG. 15A and FIG. 15B illustrate predictive detection at each of select gates A and B at an optional timing. Upper diagrams of FIG. 15A and FIG. 15B are graphs indicating threshold voltage distribution. Lower diagrams of FIG. 15A and FIG. 15B are graphs indicating a relation between the threshold voltage and the physical column.

Operations illustrated in FIG. 15A and FIG. 15B are performed by designating a select gate/dummy word line WL for checking the threshold voltage. A target of the threshold voltage is determined for each select gate/dummy word line WL, so that the upper-tail monitor UM/lower-tail monitor LM (low voltage threshold) can be set corresponding to the selected word line WL.

As a method of checking uniformity of threshold voltage distribution, two thresholds (the upper-tail monitor UM, the lower-tail monitor LM) and two search ranges (the search range Sr1, the search range Sr2) are provided. Additionally, a total number of bits having a gate voltage higher than the upper-tail monitor UM in the search range Sr1 is defined as FBC_U1, a total number of bits having a gate voltage higher than the upper-tail monitor UM in the search range Sr2 is defined as FBC_U2, a total number of bits having a gate voltage lower than the lower-tail monitor LM in the search range Sr1 is defined as FBC_L1, and a total number of bits having a gate voltage lower than the lower-tail monitor LM in the search range Sr2 is defined as FBC_L2.

The uniformity of the threshold voltage distribution is determined based on a difference between FBC_U1 and FBC_U2, and a difference between FBC_L1 and FBC_L2. In a case in which these differences exceed a certain value, it is determined that there is an anomaly in threshold voltage distribution, and status fail determination is returned.

Next, the following describes a detection operation in the configuration illustrated in FIG. 1.

The count circuit CNT acquires the number of bits in which the threshold voltage of the word line WL in the search range Sr1 exceeds a first voltage range, and the number of bits in which the threshold voltage of the word line WL in the search range Sr2 exceeds the first voltage range.

The logic circuit CTR as a detector detects an anomaly in the word line WL based on a comparison between the number of bits exceeding the first voltage range in the search range Sr1 and the number of bits exceeding the first voltage range in the search range Sr2. More specifically, in a case in which a difference between the number of bits exceeding the first voltage range in the search range Sr1 and the number of bits exceeding the first voltage range in the search range Sr2 is higher than a predetermined value, the logic circuit CTR determines that there is an anomaly in the word line WL.

In a case in which a distribution pattern of threshold voltages in the target word line WL is changeable as in the main word line WL, the first voltage range includes the upper-tail monitor UM on a high-voltage side. The logic circuit CTR detects an anomaly in the word line WL based on a difference between the number of bits higher than the upper-tail monitor UM in the search range Sr1 and the number of bits higher than the upper-tail monitor UM in the search range Sr2.

In a case in which the distribution pattern of threshold voltages in the target word line WL is fixed as in the select gate lines (SGD, SGS) and the dummy word line WL, the first voltage range includes the upper-tail monitor UM on the high-voltage side and the lower-tail monitor LM on a low-voltage side. The logic circuit CTR detects an anomaly in the word line WL based on a difference between the number of bits higher than the upper-tail monitor UM in the search range Sr1 and the number of bits higher than the upper-tail monitor UM in the search range Sr2, and a difference between the number of bits lower than the lower-tail monitor LM in the search range Sr1 and the number of bits lower than the lower-tail monitor LM in the search range Sr2.

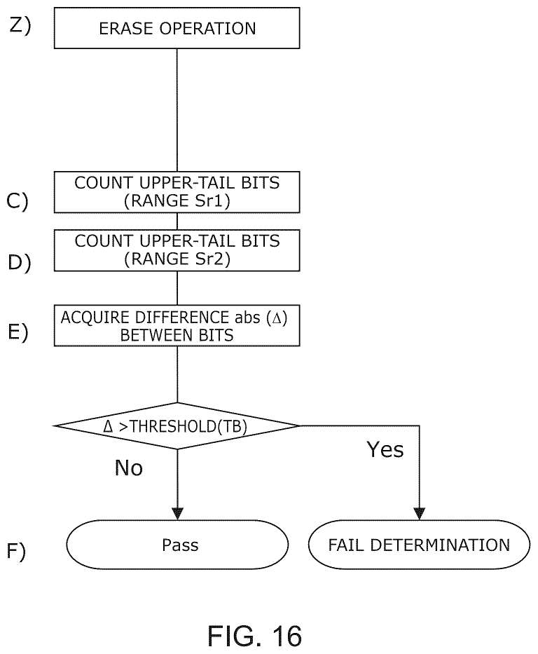

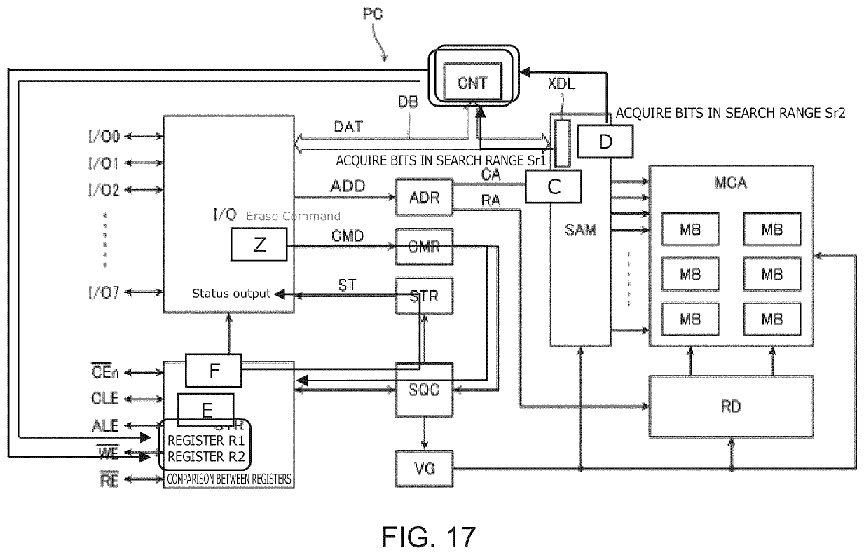

FIG. 16 is a flowchart illustrating an example of an operation of the semiconductor storage device according to the first embodiment. FIG. 17 is a schematic equivalent circuit diagram illustrating a configuration and an operation of the semiconductor storage device according to the first embodiment. In FIG. 17, the erase operation is omitted.

FIG. 16 and FIG. 17 illustrate a case of predictively detecting an anomaly in the main word line WL immediately after erasing.

At step Z, the erase operation is performed.

At step C, the count circuit CNT counts the number of bits exceeding the upper-tail monitor UM in the search range Sr1. The count circuit CNT counts the number of bits exceeding the upper-tail monitor UM in the search range Sr1 by reusing a result of erase verify in the sense amplifier module SAM. The number of bits is held in a register circuit R1 as a holder.

At step D, the count circuit CNT counts the number of bits exceeding the upper-tail monitor UM in the search range Sr2. The count circuit CNT counts the number of bits exceeding the upper-tail monitor UM in the search range Sr2 by reusing the result of erase verify in the sense amplifier module SAM. The number of bits is held in a register circuit R2 as a holder.

At step E, the logic circuit CTR acquires the number of bits exceeding the upper-tail monitor UM in the search range Sr1, and the number of bits exceeding the upper-tail monitor UM in the search range Sr2. The logic circuit CTR acquires (calculates) a difference “Δ” between bits. The difference “Δ” is a value obtained by subtracting the number of bits exceeding the upper-tail monitor UM in the search range Sr1 from the number of bits exceeding the upper-tail monitor UM in the search range Sr2. More specifically, the logic circuit CTR acquires an absolute value abs(Δ) of the difference “Δ”.

Thereafter, the logic circuit CTR determines whether the difference “Δ” exceeds a threshold TB. The threshold TB is a criterion (evaluation criterion) for performing fail determination.

At step F, in a case in which the difference “Δ” is equal to or smaller than the threshold TB (No), the logic circuit CTR determines “Pass”. In a case in which the difference “Δ” is larger than the threshold TB (Yes), the logic circuit CTR determines “Fail”.

Thereafter, a status is output via the input/output control circuit I/O.

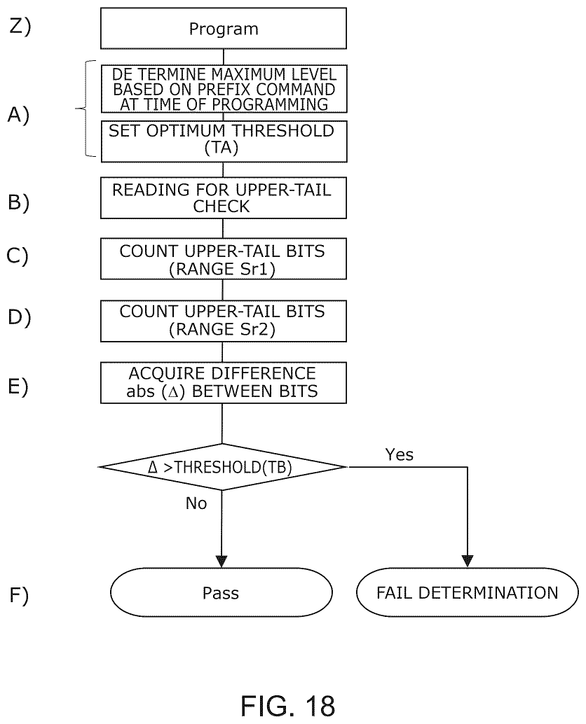

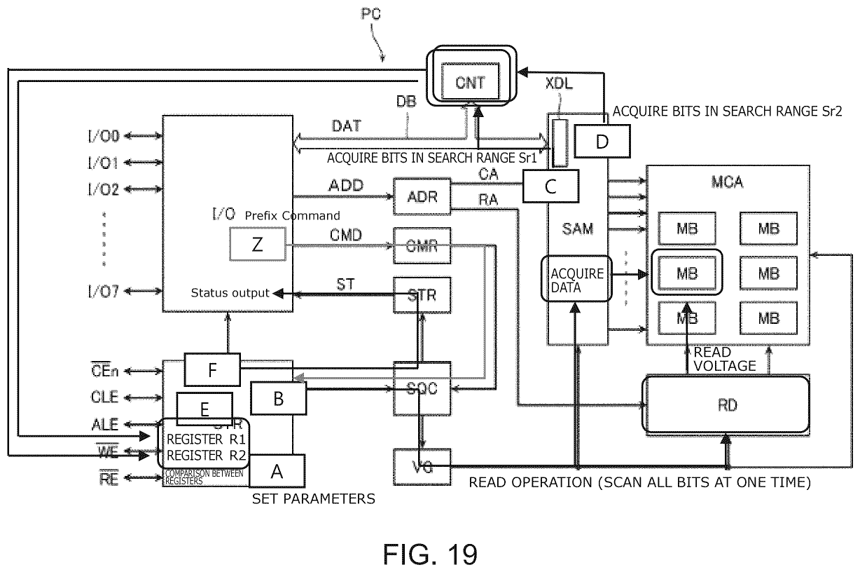

FIG. 18 is a flowchart illustrating an example of an operation of the semiconductor storage device according to the first embodiment. FIG. 19 is a schematic equivalent circuit diagram illustrating a configuration and an operation of the semiconductor storage device according to the first embodiment. In FIG. 19, a program operation is omitted.

FIG. 18 and FIG. 19 illustrate a case of predictively detecting an anomaly in the main word line WL immediately after programming.

At step Z, the program operation is performed.

At step A, the logic circuit CTR determines the maximum level of xLC (for example, SLC, MLC, TLC, or QLC) based on a prefix command at the time of programming. Thereafter, the logic circuit CTR sets an optimum threshold TA (upper-tail monitor UM).

At step B, the logic circuit CTR, the sense amplifier module SAM, and the row decoder RD perform reading for a check with the upper-tail monitor UM.

Thereafter, steps similar to step C to step F illustrated in FIG. 16 are performed.

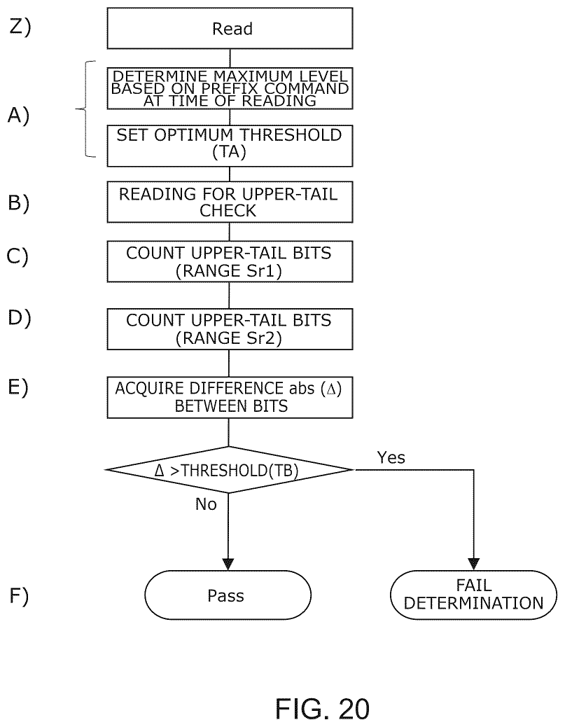

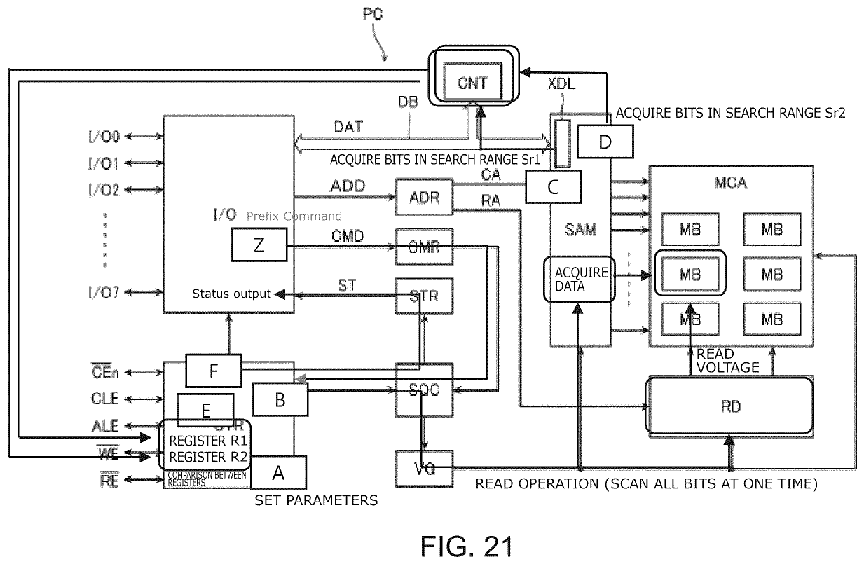

FIG. 20 is a flowchart illustrating an example of the operation of the semiconductor storage device according to the first embodiment. FIG. 21 is a schematic equivalent circuit diagram illustrating the configuration and the operation of the semiconductor storage device according to the first embodiment. In FIG. 21, the read operation is omitted.

FIG. 20 and FIG. 21 illustrate a case of predictively detecting an anomaly in the main word line WL immediately after reading.

At step Z, the read operation is performed.

At step A, the logic circuit CTR determines the maximum level of xLC (for example, SLC, MLC, TLC, or QLC) based on a prefix command at the time of reading. Thereafter, the logic circuit CTR sets the optimum threshold TA (upper-tail monitor UM).

Thereafter, steps similar to step B to step F illustrated in FIG. 18 are performed.

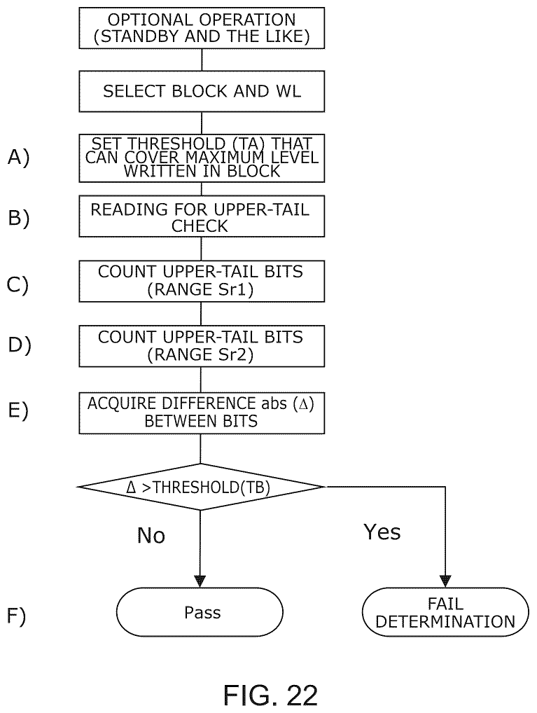

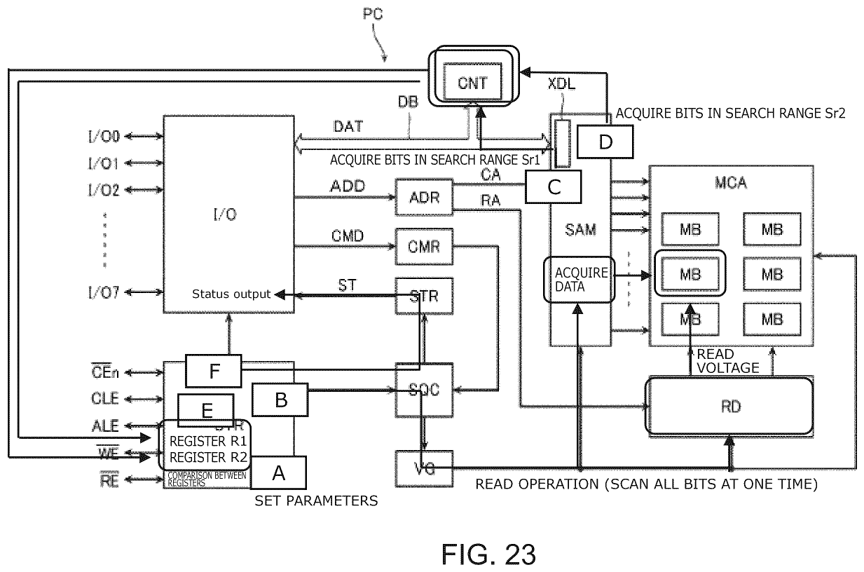

FIG. 22 is a flowchart illustrating an example of the operation of the semiconductor storage device according to the first embodiment. FIG. 23 is a schematic equivalent circuit diagram illustrating the configuration and the operation of the semiconductor storage device according to the first embodiment.

FIG. 22 and FIG. 23 illustrate a case of predictively detecting an anomaly in the main word line WL at an optional timing.

First, an optional operation is performed. The optional operation is, for example, standby and the like.

Next, a block and the word line WL are selected.

At step A, the logic circuit CTR sets the threshold TA (upper-tail monitor UM) that can cover the maximum level written in the block. The logic circuit CTR may set the threshold TA by discriminating a level written in the target block. In a case in which a level written in the cell is unknown, the logic circuit CTR may set the threshold TA that can cover the maximum level that can be written into a target chip.

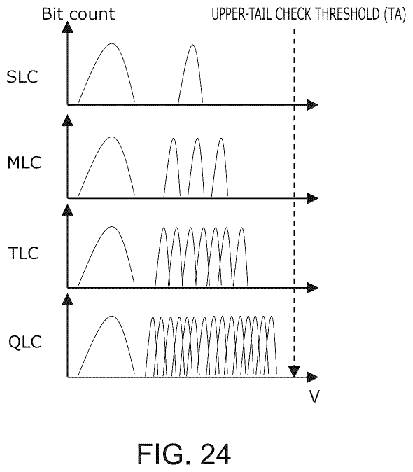

FIG. 24 is a graph illustrating distribution of threshold voltages of the semiconductor storage device according to the first embodiment.

In the example illustrated in FIG. 24, writing can be performed on the chip with SLC, MLC, TLC, or QLC. The threshold TA is set as a value that can cover the maximum level of QLC.

Thereafter, steps similar to step B to step F illustrated in FIG. 18 are performed.

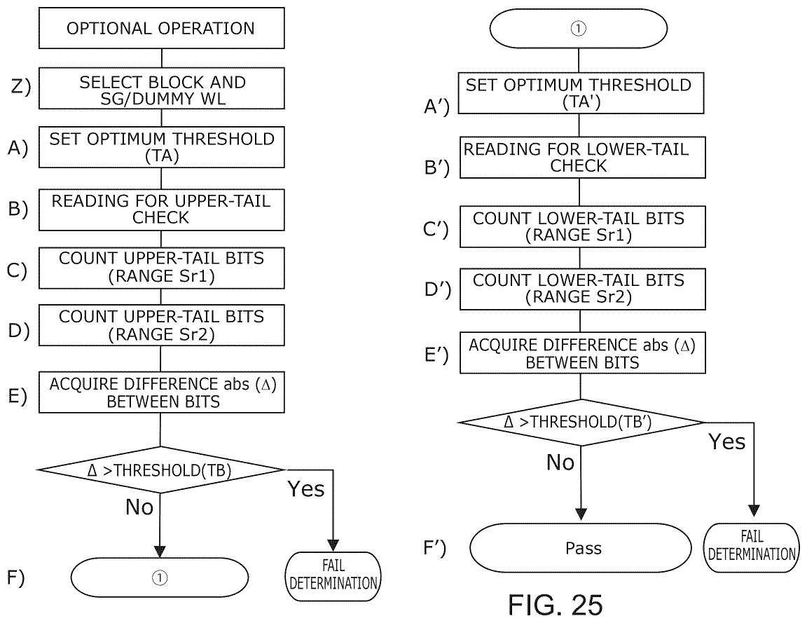

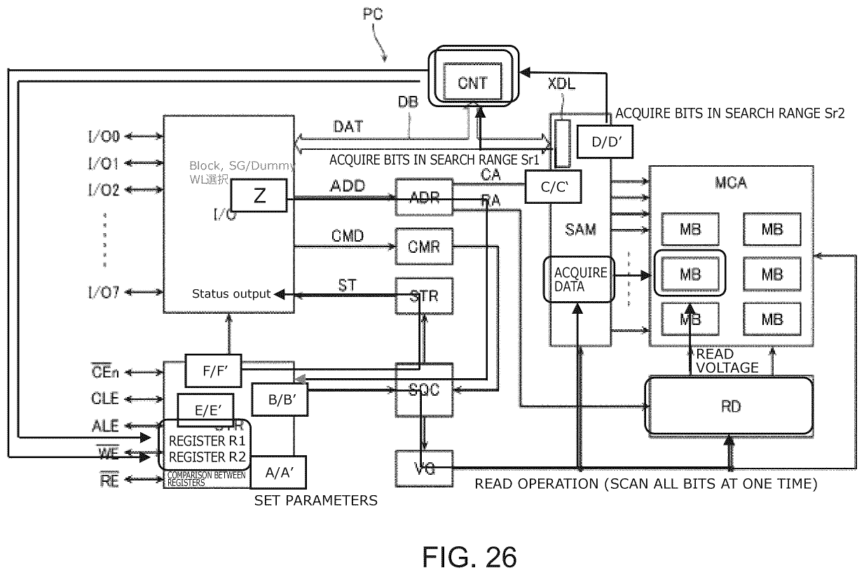

FIG. 25 is a flowchart illustrating an example of the operation of the semiconductor storage device according to the first embodiment. FIG. 26 is a schematic equivalent circuit diagram illustrating the configuration and the operation of the semiconductor storage device according to the first embodiment.

FIG. 25 and FIG. 26 illustrate a case of predictively detecting anomalies in the select gate lines (SGD, SGS) and the dummy word line WL.

First, an optional operation is performed.

At step Z, the block and the select gate lines (SGD, SGS)/dummy word line WL are selected.

At step A, a threshold voltage of a target is determined for each of the select gate lines (SGD, SGS)/dummy word line WL, so that the logic circuit CTR automatically sets the threshold TA (upper-tail monitor UM) of the select gate lines (SGD, SGS)/dummy word line WL.

Thereafter, steps similar to step B to step E illustrated in FIG. 18 are performed.

At step F, in the logic circuit CTR, in a case in which the difference “Δ” is equal to or smaller than the threshold TB (No), step A′ is performed. In a case in which the difference “Δ” is larger than the threshold TB (Yes), the logic circuit CTR determines “Fail”.

At step A′ to step E′, steps similar to step A to step E are performed on a lower tail.

At step A′, the logic circuit CTR automatically sets a threshold TA′ (lower-tail monitor LM) for the select gate lines (SGD, SGS)/dummy word line WL.

At step B′, the logic circuit CTR, the sense amplifier module SAM, and the row decoder RD performs reading for a check with the lower-tail monitor LM.

At step C′, the count circuit CNT counts the number of bits lower than the lower-tail monitor LM in the search range Sr1. The count circuit CNT counts the number of bits lower than the lower-tail monitor LM in the search range Sr1 by reusing a result of the above-described reading in the sense amplifier module SAM. The number of bits is held in the register circuit R1 as a holder.

At step D′, the count circuit CNT counts the number of bits lower than the lower-tail monitor LM in the search range Sr2. The count circuit CNT counts the number of bits lower than the lower-tail monitor LM in the search range Sr2 by reusing the result of the above-described reading in the sense amplifier module SAM. The number of bits is held in the register circuit R2 as a holder.

At step E′, the logic circuit CTR acquires the number of bits lower than the lower-tail monitor LM in the search range Sr1, and the number of bits lower than the lower-tail monitor LM in the search range Sr2. The logic circuit CTR acquires (calculates) the difference “Δ” between bits. The difference “Δ” is a value obtained by subtracting the number of bits lower than the lower-tail monitor LM in the search range Sr1 from the number of bits lower than the lower-tail monitor LM in the search range Sr2. More specifically, the logic circuit CTR acquires the absolute value abs(Δ) of the difference “Δ”.

Thereafter, the logic circuit CTR determines whether the difference “Δ” exceeds a threshold TB′. The threshold TB′ is a criterion (evaluation criterion) for performing fail determination.

At step F′, in a case in which the difference “Δ” is equal to or smaller than the threshold TB′ (No), the logic circuit CTR determines “Pass”. In a case in which the difference “Δ” is larger than the threshold TB′ (Yes), the logic circuit CTR determines “Fail”.

As described above, according to the first embodiment, the number of bits in which the threshold voltage of the word line WL in the search range Sr1 exceeds the first voltage range, and the number of bits in which the threshold voltage of the word line WL in the search range Sr2 exceeds the first voltage range are acquired. Additionally, an anomaly in the word line WL is detected based on a comparison between the number of bits exceeding the first voltage range in the search range Sr1 and the number of bits exceeding the first voltage range in the search range Sr2. Due to this, a defective cell can be predictively detected.

Typically, a timing when a memory block is marked as a bad block is when erasing/programming is performed and a status fails, or when ECC correction cannot be succeeded at the time of reading. However, marking a bad block may also include “a fault mode in which a bad block is marked at a moment when a cell is broken”, and “a fault mode in which an operation is continued in a state in which there is an anomaly in a cell, and the state is gradually deteriorated to be marked as a bad block”.

In the former fault, predictive detection cannot be performed. However, in the latter fault, the fault can be predictively detected if a function of checking an anomaly in the cell at an optional timing can be introduced.

The present embodiment is a function of acquiring the threshold voltage for the optional word line WL at an optional timing, and checking uniformity of threshold voltage distribution in the word line to be reflected in the status. Normally, in a case of a normal cell, column dependence is not found in the threshold voltage distribution. However, in a case in which there is an anomaly in the cell, a threshold voltage distribution anomaly exhibiting column dependence may be observed as a sign. According to the present embodiment, an anomaly in the threshold voltage distribution can be detected, and a fault can be detected to be marked as a bad block before occurrence of a fault for which ECC correction cannot be succeeded (predictive detection). At this point, an anomaly of the threshold voltage can be determined by limiting and dividing the search range, and comparing threshold voltages in two different ranges in the block.

At least part of a data processing method for the semiconductor storage device according to the present embodiment may be configured as hardware, or may be configured as software. In a case of being configured by software, a program that implements a function of at least part of the data processing method may be stored in a recording medium such as a flexible disk and a CD-ROM, and the program may be read and executed by a computer. The recording medium is not limited to a removable medium such as a magnetic disc and an optical disc, but may be a fixed recording medium such as a hard disk device and a memory. A program that implements a function of at least part of the data processing method may be distributed via a communication line (including wireless communication) such as the Internet. Additionally, the program may be distributed, in a state of being encrypted, modulated, or compressed, via a wired line or a wireless line such as the Internet or while being stored in a recording medium.

While certain embodiments have been described, these embodiments have been presented by way of example only, and are not intended to limit the scope of the inventions. Indeed, the novel methods and systems described herein may be embodied in a variety of other forms; furthermore, various omissions, substitutions and changes in the form of the methods and systems described herein may be made without departing from the spirit of the inventions. The accompanying claims and their equivalents are intended to cover such forms or modifications as would fall within the scope and spirit of the inventions.

1. A detection method comprising:
acquiring the number of bits in which a threshold voltage of a word line in a first column range exceeds a first voltage range, and the number of bits in which a threshold voltage of the word line in a second column range exceeds the first voltage range; and
detecting an anomaly in the word line based on a comparison between the number of bits exceeding the first voltage range in the first column range and the number of bits exceeding the first voltage range in the second column range.

2. The detection method according to claim 1, wherein
the word line is a word line in which a distribution pattern of threshold voltages is changeable,
the first voltage range includes a high voltage threshold on a high-voltage side, and
detecting an anomaly in the word line includes detecting an anomaly in the word line based on a difference between the number of bits higher than the high voltage threshold in the first column range and the number of bits higher than the high voltage threshold in the second column range.

3. The detection method according to claim 2, wherein the high voltage threshold is higher than a maximum level of a distribution pattern of threshold voltages at the time of erasing, reading, or programming, or a maximum level that is able to be taken by a threshold voltage.

4. The detection method according to claim 1, wherein
the word line is a word line in which a distribution pattern of threshold voltages is fixed,
the first voltage range includes
a high voltage threshold on a high-voltage side, and
a low voltage threshold on a low-voltage side, and
detecting an anomaly in the word line includes detecting an anomaly in the word line based on a difference between the number of bits higher than the high voltage threshold in the first column range and the number of bits higher than the high voltage threshold in the second column range, and a difference between the number of bits lower than the low voltage threshold in the first column range and the number of bits lower than the low voltage threshold in the second column range.

5. The detection method according to claim 4, wherein the word line is a select gate line or a dummy word line.

6. The detection method according to claim 1, wherein
the first column range is one of a connector of the word line and the other end of the word line on the opposite side of one end on the connector side, the connector being connected to a contact, and
the second column range is the other one of the connector and the other end.

7. The detection method according to claim 1, wherein detecting an anomaly in the word line includes determining that there is an anomaly in the word line in a case in which a difference between the number of bits exceeding the first voltage range in the first column range and the number of bits exceeding the first voltage range in the second column range is higher than a predetermined value.

8. The detection method according to claim 2, wherein
the first column range is one of a connector of the word line and the other end of the word line on the opposite side of one end on the connector side, the connector being connected to a contact, and
the second column range is the other one of the connector and the other end.

9. The detection method according to claim 3, wherein
the first column range is one of a connector of the word line and the other end of the word line on the opposite side of one end on the connector side, the connector being connected to a contact, and
the second column range is the other one of the connector and the other end.

10. The detection method according to claim 4, wherein
the first column range is one of a connector of the word line and the other end of the word line on the opposite side of one end on the connector side, the connector being connected to a contact, and
the second column range is the other one of the connector and the other end.

11. The detection method according to claim 5, wherein
the first column range is one of a connector of the word line and the other end of the word line on the opposite side of one end on the connector side, the connector being connected to a contact, and
the second column range is the other one of the connector and the other end.

12. The detection method according to claim 2, wherein detecting an anomaly in the word line includes determining that there is an anomaly in the word line in a case in which a difference between the number of bits exceeding the first voltage range in the first column range and the number of bits exceeding the first voltage range in the second column range is higher than a predetermined value.

13. The detection method according to claim 3, wherein detecting an anomaly in the word line includes determining that there is an anomaly in the word line in a case in which a difference between the number of bits exceeding the first voltage range in the first column range and the number of bits exceeding the first voltage range in the second column range is higher than a predetermined value.

14. The detection method according to claim 4, wherein detecting an anomaly in the word line includes determining that there is an anomaly in the word line in a case in which a difference between the number of bits exceeding the first voltage range in the first column range and the number of bits exceeding the first voltage range in the second column range is higher than a predetermined value.

15. The detection method according to claim 5, wherein detecting an anomaly in the word line includes determining that there is an anomaly in the word line in a case in which a difference between the number of bits exceeding the first voltage range in the first column range and the number of bits exceeding the first voltage range in the second column range is higher than a predetermined value.

16. The detection method according to claim 6, wherein detecting an anomaly in the word line includes determining that there is an anomaly in the word line in a case in which a difference between the number of bits exceeding the first voltage range in the first column range and the number of bits exceeding the first voltage range in the second column range is higher than a predetermined value.

17. A semiconductor storage device comprising:
a bit line;
a memory transistor electrically connected to the bit line;
a source line electrically connected to the memory transistor;
a word line electrically connected to a gate electrode of the memory transistor;
a counter configured to acquire the number of bits in which a threshold voltage of the word line in a first column range exceeds a first voltage range, and the number of bits in which a threshold voltage of the word line in a second column range exceeds the first voltage range; and
a detector configured to detect an anomaly in the word line based on a comparison between the number of bits exceeding the first voltage range in the first column range and the number of bits exceeding the first voltage range in the second column range.

18. The semiconductor storage device according to claim 17, further comprising:
a holder configured to hold the number of bits exceeding the first voltage range in the first column range and the number of bits exceeding the first voltage range in the second column range.
